(19) United States
(12) Patent Application Publication
(10) Pub. No.: US 2010/0046162 A1
(43) Pub. Date: Feb. 25, 2010

(54) CASING, METHOD FOR MANUFACTURING THE SAME, AND ELECTRONIC DEVICE HAVING THE SAME

(75) Inventors: Yen-Liang CHEN, Taipei (TW); Wei-Chun CHIEN, Taipei (TW); Ching-Hao YU, Taipei (TW); Chien-Hsu HOU, Taipei (TW); Martijn BALLER, Taipei (TW); Jia-Rong LIN, Taipei (TW); Ching-Ying LEE, Taipei (TW); Yung-Chie HUANG, Taipei (TW); Chi-Chen LIN, Taipei (TW); Meng-Hsuan SHIH, Taipei (TW)

Correspondence Address: Muncy, Geissler, Olds & Lowe, PLLC, P.O. BOX 1364, FAIRFAX, VA, 22038-1364, US

(73) Assignee: PEGATRON CORPORATION, Taipei City (TW)

(21) Appl. No.: 12/543,895

(22) Filed: Aug. 19, 2009

(30) Foreign Application Priority Data
Aug. 20, 2008 (TW) 097131751

(51) Int. Cl. G06F 1/16; B23P 17/04; H05K 5/00; A47B 97/00; G09F 11/00

(52) U.S. Cl. 361/679.55; 29/592.1; 361/679.01; 312/352; 40/1

(57) ABSTRACT

A casing includes a main body and a covering layer. The main body has a first transparent area and a second transparent area disposed as mirror images. Light passes through the first transparent area and the second transparent area. The covering layer covers the second transparent area and has a transmittance gradient. A method for manufacturing the casing and an electronic device having the casing are also disclosed.

### CROSS REFERENCE TO RELATED APPLICATIONS

This Non-provisional application claims priority under 35 U.S.C. §119(a) on Patent Application No(s). 097131751 filed in Taiwan, Republic of China on Aug. 20, 2008, the entire contents of which are hereby incorporated by reference.

### BACKGROUND OF THE INVENTION

1. Field of Invention

The invention relates to a casing and, more particularly, to a casing, a method for manufacturing the casing, and an electronic device having the casing.

2. Related Art

To facilitate identification of an electronic device, such as a type or a brand, specific drawings or characters are often designed on a casing of the electronic device. However, the designs of the drawings, characters, or symbols are just formed by printing or pasting. Therefore, when the ambient light is not enough, the electronic device cannot be effectively identified.

### SUMMARY OF THE INVENTION

This invention provides a casing providing different displaying effects by a light source, a method for manufacturing the casing, and an electronic device having the casing.

According to one aspect of the invention, the casing includes a main body and a covering layer. The main body has a first transparent area and a second transparent area formed as mirror images each other. Light passes through the first transparent area and the second transparent area. The covering layer with a gradient transmittance covers the second transparent area.

According to another aspect of the invention, the electronic device includes a casing and a light source module. The light source module is disposed in the casing. The casing includes a main body and a covering layer. The main body has a first transparent area and a second transparent area formed as mirror images each other. Light emitted from the light source module passes through the first transparent area and the second transparent area. The covering layer with a transmittance gradient covers the second transparent area.

According to a third aspect of the invention, the method for manufacturing the casing includes the following steps. First, a main body is provided. Then, a first transparent area and a second transparent area are formed as mirror images each other at the main body. Finally, a covering layer with a transmittance gradient is covered on the second transparent area.

In one embodiment of the invention, the first transparent area and the second transparent area may have the same shape.

In one embodiment of the invention, the first transparent area and the second transparent area may present drawings, characters, or symbols.

In one embodiment of the invention, the covering layer may be formed by pasting, spraying paint, jetting ink, transfer printing, dot printing, screen painting, or printing.

In one embodiment of the invention, the main body may be made of glass or a polymer material. The polymer material may be selected from the group consisting of polyethyleneterephthalate, polyester, polycarbonates, polyacrylates, polystyrene, and a combination thereof.

In one embodiment of the invention, the light source module may be a direct-type light source module or a side-type light source module.

In one embodiment of the invention, in the step of forming the first transparent area and the second transparent area formed as mirror images each other at the main body, the first transparent area and the second transparent area may be defined by providing a coloring material on the main body. The coloring material may be formed by spreading, pasting, spraying paint, transfer printing, or printing.

In one embodiment of the invention, in the step of forming the first transparent area and the second transparent area at the main body, the first transparent area and the second transparent area may be respectively formed by injection molding or co-injection molding.

In one embodiment of the invention, after the step of forming the first transparent area and the second transparent area at the main body, drawings, characters, or symbols may be formed on the first transparent area and the second transparent area.

In one embodiment of the invention, the covering layer may be a single structure or a multilayer structure.

In one embodiment of the invention, the main body may be made of a transparent material.

In the invention, different light and reflection effects are visually provided for users by the transparent areas and the covering layer with a gradient transmittance.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a casing according to a preferred embodiment of the invention;

FIG. 2 is a schematic diagram showing an electronic device according to a preferred embodiment of the invention; and

FIG. 3 is a flowchart showing a method for manufacturing a casing according to a preferred embodiment of the invention.

### DETAILED DESCRIPTION OF THE INVENTION

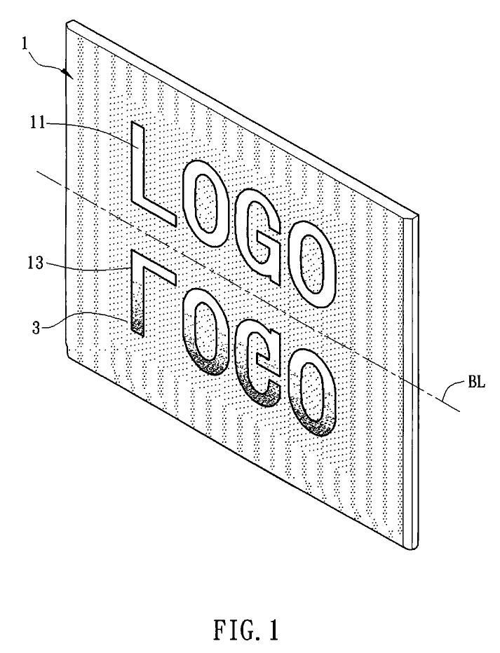

FIG. 1 is a schematic diagram showing a casing according to a preferred embodiment of the invention. In the embodiment, a casing includes a main body 1 and a covering layer 3. The main body 1 has a first transparent area 11 and a second transparent area 13 disposed as mirror images. Light emitted from a light source module passes through the first transparent area 11 and the second transparent area 13. The first transparent area 11 and the second transparent area 13 may be disposed horizontally, vertically, or slantingly as mirror images.

In the embodiment, the main body 1 made of glass is taken for example. The main body 1 may also be made of a polymer material or other transparent materials. However, the invention is not limited thereto. The polymer material is selected from the group consisting of polyethyleneterephthalate, polyester, polycarbonates, polyacrylates, polystyrene, and a combination thereof.

In the embodiment, the first transparent area 11 and the second transparent area 13 have the same shape, and they have symbols (as shown in FIG. 1, ‘LOGO’ is taken for example in the embodiment). The first transparent area 11 and the second transparent area 13 are formed as mirror images along a reference line BL. In the embodiment, the first transparent area 11 and the second transparent area 13 present the symbols. However, the first transparent area 11 and the second transparent area 13 may include other significant characters or drawings.

The light source module (not shown) is disposed in the casing, and the covering layer 3 is disposed at the second transparent area 13 of the casing. Since the covering layer 3 has a gradient transmittance, light emitted from the light source module disposed in the casing and passing through the second transparent area 13 is different with positions. In the embodiment, a gradual change (such as gradually fading) is taken for example. The covering layer 3 may also be in the form of thickening or thinning along the reference line BL, or it may be in the form of fading radially from central to outside or thickening radially from central to outside. However, the invention is not limited thereto, as long as different light and reflection effects can be provided for users. The covering layer 3 is formed by pasting, spraying paint, jetting ink, transfer printing, dot printing, screen painting, or printing.

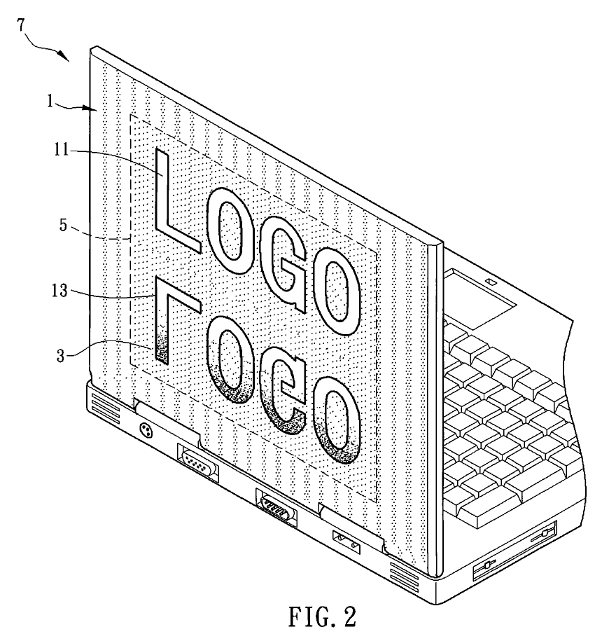

FIG. 2 is a schematic diagram showing an electronic device according to a preferred embodiment of the invention. In the embodiment, a notebook computer as an electronic device 7 is taken for example. The electronic device 7 may be a personal digital assistant, an electronic book, a mobile communication device, or any other portable electronic device. However, the invention is not limited thereto.

In the embodiment, the electronic device 7 includes a casing and a light source module 5. The casing includes a main body 1 and a covering layer 3. The light source module 5 is disposed in the casing. The structure of the casing is described in detail above. Therefore, it is not described for a concise purpose.

The light source module 5 may be a direct-type light source module or a side-type light source module. When light emitted from the light source module 5 passes through the first transparent area 11 of the main body 1, the first transparent area 11 presents a light and reflection effect (such as a transparency effect). When the light passes through the second transparent area 13, since the covering layer 3 with a gradient transmittance covers the second transparent area 13, the light passing through the second transparent area 13 is different with different positions. Therefore, the second transparent area 13 can additionally present another light and reflection effect (such as a three-dimension effect or a space effect). When users see that light is transmitted from the first transparent area 11 and the second transparent area 13 of the electronic device 7, they can feel the bottom of the symbol like a reflection in water with a gradually fading effect.

In addition, if a color of a nontransparent area of the main body 1 is the same as a background color (such as a color of a backboard of the light source module), when the light source module 5 does not emit light, the casing of the electronic device 7 does not present the symbol. If a background color is provided for the first transparent area 11 of the main body 1 (such as a transparent metal color), when the light source module 5 does not emit light, the electronic device 7 still presents the first transparent area 11 having the background color.

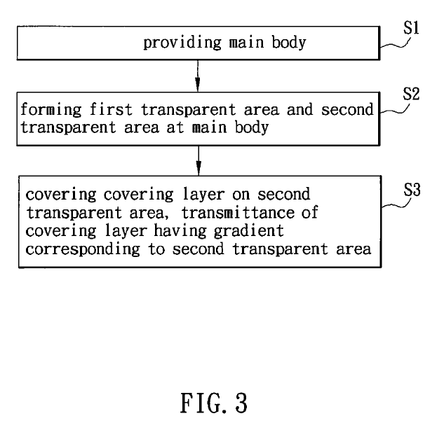

FIG. 3 is a flowchart showing a method for manufacturing a casing according to a preferred embodiment of the invention. The method for manufacturing a casing includes the steps from S1 to S3. Please refer to FIGS. 1-3 together.

First, in step S1, a main body 1 is provided. Then, in step S2, a first transparent area 11 and a second transparent area 13 is formed at the main body 1. The first transparent area 11 and the second transparent area 13 may include other significant characters, drawings, or symbols.

In step S3, a covering layer 3 is covered on the second transparent area 13. The covering layer 3 has a transmittance gradient. The covering layer 3 can be a single structure or a multilayer structure. Thus, the second transparent area 13 can have different transmittances by the covering layer 3. The covering layer 3 is formed by pasting, spraying paint, jetting ink, transfer printing, dot printing, screen printing, or printing.

In step S2, the main body 1 can be made of a transparent material, and the first transparent area 11 and the second transparent area 13 can be simultaneously formed at the main body 1 by injection molding or co-injection molding.

In addition, according to practical needs, in step S2, the first transparent area 11 and the second transparent area 13 is defined by providing a coloring material on the main body 1, and the coloring material is provided by spreading, pasting, spraying paint, transfer printing, or printing.

To sum up, different light and reflection effects are visually provided for users by the transparent areas and the covering layer with a gradient transmittance.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A casing comprising:
a main body having a first transparent area and a second transparent area formed as mirror images each other, light passing through the first transparent area and the second transparent area; and
a covering layer with a transmittance gradient covering the second transparent area.

2. The casing according to claim 1, wherein the first transparent area and the second transparent area have the same shape.

3. The casing according to claim 1, wherein the first transparent area and the second transparent area present drawings, characters, or symbols.

4. The casing according to claim 1, wherein the covering layer is formed by pasting, spraying paint, jetting ink, transfer printing, dot printing, screen painting, or printing.

5. The casing according to claim 1, wherein the main body is made of glass or a polymer material.

6. The casing according to claim 5, wherein the polymer material is selected from the group consisting of polyethyleneterephthalate (PET), polyester, polycarbonates, polyacrylates, polystyrene, and a combination thereof.

7. An electronic device comprising:
a light source module; and
a casing including a main body and a covering layer, the light source module disposed in the casing, the main body having a first transparent area and a second transparent area formed as mirror images each other, light emitted from the light source module passing through the first transparent area and the second transparent area, the covering layer with and having a gradient transmittance covering the second transparent area.

8. The electronic device according to claim 7, wherein the first transparent area and the second transparent area have the same shape.

9. The electronic device according to claim 7, wherein the first transparent area and the second transparent area present drawings, characters, or symbols.

10. The electronic device according to claim 7, wherein the covering layer is formed by pasting, spraying paint, jetting ink, transfer printing, dot printing, screen painting, or printing.

11. The electronic device according to claim 7, wherein the main body is made of glass or a polymer material.

12. The electronic device according to claim 11, wherein the polymer material is selected from the group consisting of polyethyleneterephthalate (PET), polyester, polycarbonates, polyacrylates, polystyrene, and a combination thereof.

13. The electronic device according to claim 7, wherein the light source module is a direct-type light source module or a side-type light source module.

14. The electronic device according to claim 7, wherein the electronic device is a notebook computer, a personal digital assistant, an electronic book, or a mobile communication device.

15. A method for manufacturing a casing, the method comprising the steps of:
providing a main body;
forming a first transparent area and a second transparent area as mirror images each other at the main body; and
covering a covering layer with a gradient transmittance on the second transparent area.

16. The method for manufacturing a casing according to claim 15, wherein in the step of forming the first transparent area and the second transparent area as mirror images each other at the main body, the first transparent area and the second transparent area are separated by providing a coloring material for one portion of the main body.

17. The method for manufacturing a casing according to claim 16, wherein the coloring material is provided on the main body by spreading, pasting, spraying paint, transfer printing, or printing.

18. The method for manufacturing a casing according to claim 15, wherein in the step of forming the first transparent area and the second transparent area at the main body, the first transparent area and the second transparent area are respectively formed by injection molding or co-injection molding.

19. The method for manufacturing a casing according to claim 15, wherein after the step of forming the first transparent area and the second transparent area as mirror images each other at the main body, the first transparent area and the second transparent area including drawings, characters, or symbols.

20. The method for manufacturing a casing according to claim 15, wherein the covering layer is formed by pasting, spraying paint, jetting ink, transfer printing, dot printing, screen painting, or printing.

21. The method for manufacturing a casing according to claim 15, wherein the covering layer is a single layer structure or a multilayer structure.

22. The method for manufacturing a casing according to claim 15, wherein the main body is made of a transparent material.
